(19) United States
(12) Patent Application Publication
(10) Pub. No.: US 2022/0277931 A1
(43) Pub. Date: Sep. 1, 2022

(54) APPARATUS FOR PROCESSING SUBSTRATE WITH PLASMA

(71) Applicant: EUGENE TECHNOLOGY CO., LTD., Yongin-si, Gyeonggi-do (KR)

(72) Inventor: Yoon Seok CHOI, Suwon-si, Gyeonggi-do (KR)

(73) Assignee: EUGENE TECHNOLOGY CO., LTD., Yongin-si, Gyeonggi-do (KR)

(21) Appl. No.: 17/627,651

(22) PCT Filed: Jul. 17, 2020
(86) PCT No.: PCT/KR2020/009429

§ 371 Date: Jan. 15, 2022

(30) Foreign Application Priority Data
Jul. 17, 2019 (KR) 10-2019-0086585

(51) Int. Cl. H01J 37/32

(52) U.S. Cl. CPC H01J 37/3211; H01J 37/32119; H01J 37/3244; H01J 37/32651

(57) ABSTRACT

In accordance with an exemplary embodiment of the present invention, an apparatus for processing substrate with a plasma, the apparatus comprising: a chamber forming an inner space in which a processing gas is supplied; a substrate holder installed in the inner space to support a substrate; a dielectric window positioned on the substrate holder; at least one antenna installed outside the dielectric window to generate an induced plasma from the processing gas supplied to the inner space; and at least one metal shield installed between the antenna and the induced plasma.

### TECHNICAL FIELD

The present invention relates to an apparatus for processing substrate with a plasma and, more particularly, to an apparatus for processing substrate with a plasma preventing an erosion of window due to a capacitive coupling between an antenna coil and a plasma.

### BACKGROUND ART

RF plasma is used in the manufacture of an integrated circuits, a flat panel display, and other devices. The RF plasma source should generally be able to sustain a stable plasma in a variety of process gases and under a variety of conditions.

Plasma sources for obtaining the above-mentioned requirements for plasma processing are known, and an inductively coupled plasma(ICP) source can generate high-density plasma using a standard RF power of 13.56 MHz. Furthermore, it is known to use a multi-coil ICP source to provide good control and high plasma density. For example, one or more coils are placed on top of the dielectric window and powered from RF power.

However, in the case of the ICP source, due to the very high voltage applied to the coil, a capacitive coupling occurs between the ICP source and the plasma, causing an erosion to the dielectric window, so that a cost of managing an equipment increases and the process yield deteriorates.

### DISCLOSURE OF THE INVENTION

### Technical Problem

The present invention provides an apparatus for processing substrate with a plasma that is capable of preventing an erosion to a dielectric window.

Another object of the present invention is to provide an apparatus for processing substrate with a plasma that is capable of generating a high-density plasma.

Further another object of the present invention will become evident with reference to following detailed descriptions and drawings.

### Technical Solution

In accordance with an exemplary embodiment of the present invention, an apparatus for processing substrate with a plasma, the apparatus comprising: a chamber forming an inner space in which a processing gas is supplied; a substrate holder installed in the inner space to support a substrate; a dielectric window positioned on the substrate holder; at least one antenna installed outside the dielectric window to generate an induced plasma from the processing gas supplied to the inner space; and at least one metal shield installed between the antenna and the induced plasma.

The metal shield may have a shape corresponding to the antenna, and the metal shield may be floating.

The metal shield may have a shape corresponding to the antenna, and the metal shield may be grounded.

The dielectric window may comprise: a plurality of accommodating spaces recessed from an upper surface of the dielectric window, the metal shield and the antenna are accommodated sequentially from the inside of the accommodating space; and a plurality of generating space recessed from a lower surface of the dielectric window to be located at the same height as the antenna, so that the induced plasma is generated between the accommodating spaces, wherein the accommodating spaces and the generating spaces are alternately disposed from the center of the dielectric window toward the edge of the dielectric window.

The antenna may comprise: a first antenna having a ring-shape of a first diameter; and a second antenna having a ring-shape of a second diameter, the second diameter is larger than the first diameter.

The accommodating spaces may comprise: a ring-shaped first accommodating space in which the first antenna is accommodated; and a ring-shaped second accommodating space in which the second antenna is accommodated.

The metal shield may have a plurality of slits formed radially from the center of the antenna.

The apparatus may further comprise an insulating shield installed between the antenna and the metal shield.

### Advantageous Effects

According to an embodiment of the present invention, it is possible to prevent capacitive coupling due to a very high voltage applied to the coil, thereby preventing an erosion of the dielectric window. In addition, it is possible to providing generating spaces in which a processing gas is supplied between the receiving spaces in which the antennas are accommodated, so that a high-density plasma can be generated.

### DESCRIPTION OF DRAWINGS

FIG. 1 shows a plasma and a sheath generated by an antenna coil in a general plasma processing apparatus.

FIG. 2 shows a change in voltage applied to the antenna coil shown in FIG. 1.

FIG. 3 shows a voltage applied to the antenna coil shown FIG. 1 and an erosion of the dielectric window.

FIG. 4 shows an apparatus for processing substrate with plasma according to an embodiment of the present invention.

FIG. 5 shows the antenna coil, the insulating shield, and the metal shield accommodated in the dielectric window shown in FIG. 4.

FIG. 6 shows a magnetic field formed by the antenna coil shown in FIG. 4.

FIG. 7 and FIG. 8 show the metal shield shown in FIG. 4.

FIG. 9 is another embodiment showing the antenna coil, the insulating shield, and the metal shield accommodated in the dielectric window shown in FIG. 4.

### BEST MODE

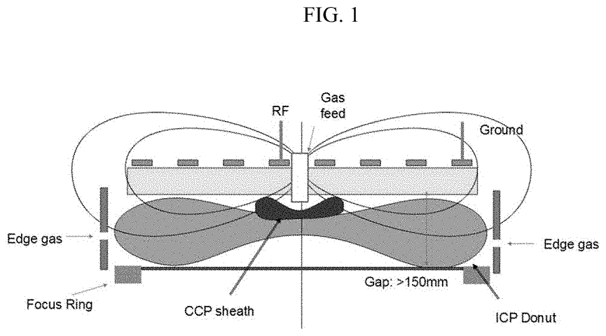

Hereinafter, preferred embodiments of the present invention will be described in more detail with reference to FIGS. 1 to 9. The present invention may be embodied in different forms and should not be constructed as limited to the embodiments set forth herein. Rather, the embodiments are provided to explain the present invention more completely to those skilled in the art to which the present invention pertains. Therefore, the dimensions of each component shown in the figures are exaggerated for clarity of description.

FIG. 1 shows a plasma and a sheath generated by an antenna coil in a general plasma processing apparatus. As shown in FIG. 1, a substrate is placed on a focus ring, and a dielectric window is placed above the substrate. The processing gas is supplied from the upper and side portions of the substrate, and the antenna coil is installed above the dielectric window to generate plasma from the processing gas. One end of the antenna coil located at the center is connected to the RF power and the other end located at the edge is grounded. However, in reverse, the other end located at the edge may be connected to the RF power and the one end located at the center may be grounded, and a capacitor may be interposed between the antenna coil and the ground.

At this time, the plasma is generated in a donut shape above the substrate, a very high voltage applied to the antenna coil in this process generates a capacitively coupled with the plasma, so that a sheath is formed strongly in the lower center of the dielectric window.

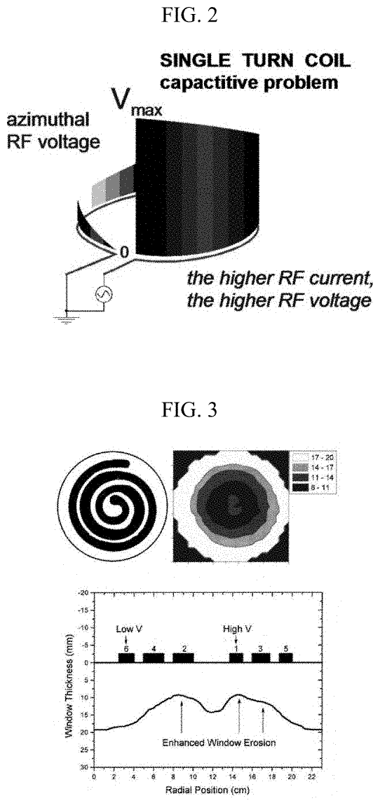

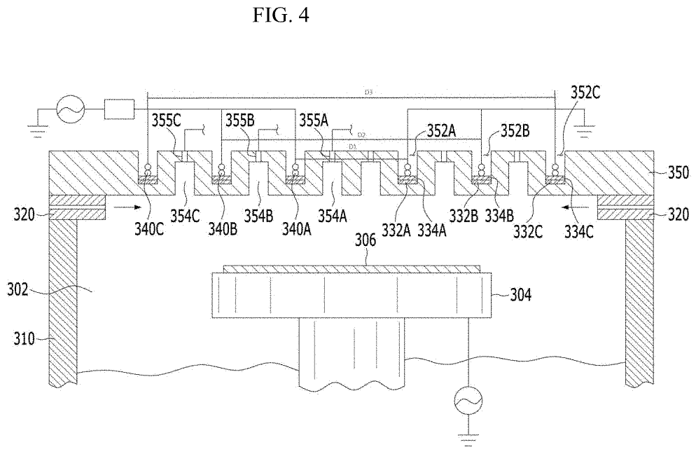

FIG. 2 shows a change in voltage applied to the antenna coil shown in FIG. 1, FIG. 3 shows a voltage applied to the antenna coil shown FIG. 1 and an erosion of the dielectric window. As shown in FIG. 2, the voltage applied to the antenna coil is highest at one end connected to the RF power and becomes 0V at the other end connected to the ground, the voltage gradually decreases from one end to the other end. That is, as shown in FIG. 3, #1 corresponding to one end represents the highest voltage, and #6 corresponding to the other end represents the lowest voltage.

In addition, it can be seen that the degree of an erosion in the dielectric window is large in a part corresponding to #1/#2 representing a high voltage, and the degree of an erosion is small in a part corresponding to #5/#6 representing a low voltage. For reference, in FIG. 3, the upper left represents the shape of the antenna coil, and the upper right represents the thickness of the dielectric window schematically.

Summarizing the above, there is a problem that a sheath is formed due to capacitive coupling in a portion of the antenna coil to which a high voltage is applied, and thus the dielectric window is damaged by sputtering. Conversely, it can be seen that the dielectric window is relatively less damaged in a portion of the antenna coil to which a low voltage is applied. Therefore, in order to prevent damage to the dielectric window, it is necessary to limit the sheath formation and the like.

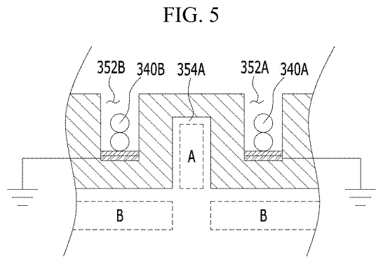

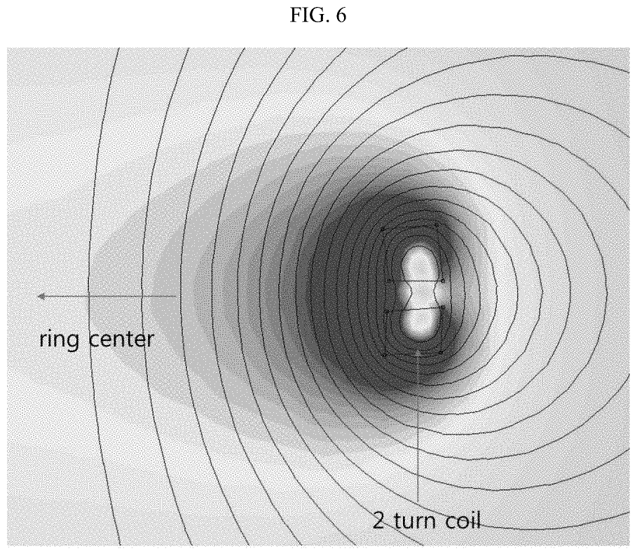

FIG. 4 shows an apparatus for processing substrate with plasma according to an embodiment of the present invention, FIG. 5 shows the antenna coil, the insulating shield, and the metal shield accommodated in the dielectric window shown in FIG. 4. As shown in FIG. 4, the chamber 310 has an inner space 302 to which processing gas is supplied, and the substrate holder 304 supports a substrate 306 such as a semiconductor wafer in the inner space 302. The dielectric window 350 is positioned above the substrate holder 304 and is disposed substantially parallel to the substrate 306.

The dielectric window 350 has receiving spaces 352A, 352B and 352C and generating spaces 354A, 354B and 354C. The receiving spaces 352A, 352B and 352C are recessed from the upper surface of the dielectric window 350, and the generating spaces 354A, 354B, and 354C are recessed from the lower surface of the dielectric window 350. As shown in FIG. 4, the generating spaces 354A, 354B, and 354C and the receiving spaces 352A, 352B, and 352C are alternately arranged from the center of the dielectric window 350 to the edge, and have a shape corresponding the antenna 340A, 340B and 340C.

Antenna coils 340A, 340B and 340C are accommodated in the receiving spaces 352A, 352B, and 352C, and disposed outside the innermost generating space 354A. RF power and matcher is connected to one ends antenna coils 340A, 340B, and 340C to supply power (frequency is approximately 13.56 MHz), and the other end can be grounded. However, unlike this embodiment, the other end may be connected to the capacitor and the capacitor may be grounded, and a plurality of RF powers and matchers may be respectively connected to the antenna coils 340A, 340B, and 340C to supply power individually.

As shown in FIG. 4, the antenna coils 340A, 340B, and 340C each have a cylindrical shape (helical shape) or a ring shape based on the center of the dielectric window 350, multiple antenna coils separated from each other may be used and the power distribution between the antenna coils is determined by a matcher. That is, for example, the antenna coil 340A may be a cylinder shape or a ring shape having a first diameter (D1), and the antenna coil 340B may be a cylinder shape or a ring shape having a second diameter (D2). The antenna coil 340C may have a cylindrical shape or a ring shape, which is a multilevel ring having a third diameter D3.

Specifically, the ICP source can be classified into a ring-shaped planar ICP located above the substrate, and a cylindrical ICP located around the substrate. The cylindrical antenna coil shown in FIG. 4 can be classified into a hybrid form in which both are mixed. That is, the above-described cylindrical antenna coil is located above the substrate, but has a cylindrical shape, and plasma is generated in a manner similar to that of the cylindrical ICP. The reason is to shorten the distance between the ICP source (or antenna coil) and the substrate, and to secure the uniformity of the process using three independent ICP sources. In this way, when the gap is less than 50 mm, the uniformity can be adjusted. On the other hand, the conventional ICP source has a gap of 150 mm or more.

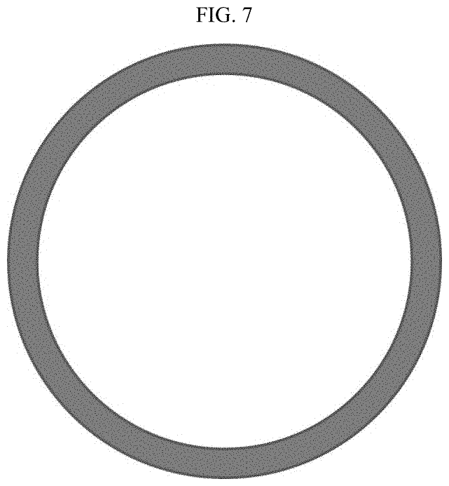

FIG. 6 shows a magnetic field formed by the antenna coil shown in FIG. 4. When power is supplied to the antenna coils 340A, 340B, and 340C described above, the antenna coils 340A, 340B, and 340C form a magnetic field. As shown in FIG. 6, it can be seen that a relatively strong magnetic field is formed in the center direction of the ring (or antenna coils), and a relatively weak magnetic field is formed under the ring of the antenna coils 340A, 340B, and 340C.

Meanwhile, in the present embodiment, a multi-antenna coil is described as an example, but one pancake-type antenna coil shown in FIGS. 1 and 3 may be used.

Metal shields 332A, 332B, and 332C and insulating shields 334A, 334B, and 334C are accommodated in the receiving spaces 352A, 352B, and 352C. Insulating shields 334A, 334B, and 334C are interposed between metal shields 332A, 332B, and 332C and the antenna coils 340A, 340B, and 340C to insulate each other.

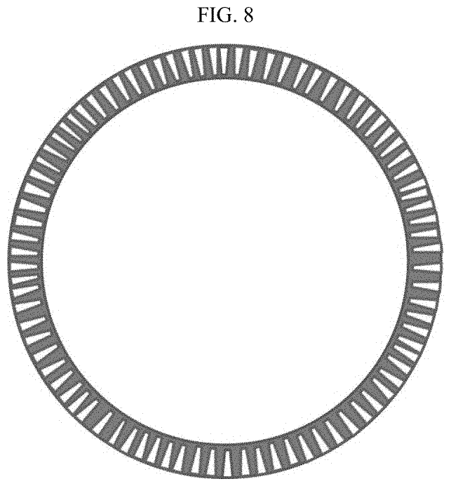

FIG. 7 and FIG. 8 show the metal shield shown in FIG. 4. In the case of the multi-antenna coil described above, the receiving spaces 352A, 352B, and 352C and the generating spaces 354A, 354B, and 354C may have a ring shape having first to third diameters, respectively. As shown in FIG. 7, the metal shields 332A, 332B, and 332C may also have a ring shape having first to third diameters, respectively.

The insulating shields 334A, 334B, and 334C may have the same shape as the metal shields 332A, 332B and 332C, or may be in the form of an insulating tape surrounding the metal shields 332A, 332B and 332C. Alternatively, the metal shields 332A, 332B, and 332C and the antenna coils 340A, 340B and 340C may be separated from each other to insulate each other.

Since the magnetic field formed in the radial direction (or the center direction) by the antenna coils 340A, 340B, and 340C is not affected by the metal shields 332A, 332B, and 332C shown in FIG. 7, so that plasma can be smoothly generated in the generating spaces 354A, 354B, and 354C located in the center direction of the antenna coils 340A, 340B, and 340C. However, since the magnetic field formed in the lower direction by the antenna coils 340A, 340B and 340C cannot proceed by the metal shields 332A, 332B, and 332C, plasma efficiency generated in the lower portion of the antenna coils 340A, 340B and 340C can be reduced. Accordingly, as shown in FIG. 8, the metal shields 332A, 332B, and 332C may have a plurality of slits, and the slits may have a shape arranged radially from the center of the metal shields. The slits provide a space through which a magnetic field formed by the antenna coils 340A, 340B, and 340C can pass, and plasma efficiency can be improved, comparing to the metal shields 332A, 332B, and 332C shown in FIG. 7.

The dielectric window 350 has a plurality of nozzle holes 355A, 355B, and 355C arranged concentrically, and each of the nozzle holes 355A, 355B, and 355C penetrates the upper wall located above the generating spaces 354A, 354B, and 354C and communicates with the generating spaces 354A, 354B, and 354C. The side nozzle 320 is installed between the dielectric window 350 and a chamber 310. The nozzle holes 355A, 355B, 355C inject processing gas supplied through a gas supply line into the generating spaces 354A, 354B, and 354C, respectively, and the side nozzle 320 injects processing gas into the inner space 302 and toward the upper portion of the substrate 306.

Hereinafter, an operation method of the present invention will be described with reference to FIGS. 4 and 5. In a state where the substrate 306 is supported by the substrate holder 304, the nozzle holes 355A, 355B, 355C and the side nozzle 320 supply processing gas, and the RF power and matcher supply power to the antenna coils 340A, 340B, and 340C. Accordingly, as will be described later, the plasma is mainly formed in the generation spaces 354A, 354B, and 354C and diffuses into the inner space 302, a process for the substrate can be performed by the plasma.

At this time, the conductive metal shields 332A, 332B, and 332C can be grounded (see FIG. 5), and the grounded metal shields 332A, 332B, and 332C) are 0V regardless of the position, so that the sheath due to capacitive coupling cannot be formed and the erosion of the dielectric window 350 can be prevented. In other words, regardless of the portions of the antenna coils 340A, 340B, and 340C to which a high voltage is applied or the portions of the antenna coils 340A, 340B, and 340C to which a low voltage is applied, the metal shields 332A, 332B, and 332C located under the antenna coils 340A, 340B, and 340C are grounded, so that no capacitive coupling occurs.

On the other hand, as described above, since a strong magnetic field is formed in the center direction of the antenna coils 340A, 340B, and 340C, the plasma can be smoothly generated in the generating spaces 354A, 354B, and 354C located in the center direction of the antenna coils 340A, 340B, and 340C. That is, as shown in FIG. 5, a relatively high-density plasma may be generated in the area A compared to the area B.

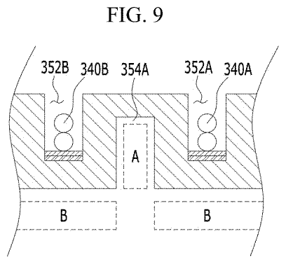

FIG. 9 is another embodiment showing the antenna coil, the insulating shield, and the metal shield accommodated in the dielectric window shown in FIG. 4. In an embodiment different from the above, the metal shields 332A, 332B, and 332C can be floated, and the metal shields 332A, 332B, and 332C have an equipotential regardless of their position. A portion to which a high voltage is applied depending on the position of the metal shields disappears, and the same potential is formed at all positions of the metal shields. Accordingly, it is possible to reduce the capacitive coupling effect concentrated in the portion where the high potential is formed, and thereby solve the problem that the dielectric window 350 is damaged by sputtering or the like. In addition, when a balanced condition is achieved by connecting a balanced capacitor between the antenna coil and the ground, the antenna coil is divided into (+) potential and (−) potential based on the center of the antenna coil. However, the metal shields are floated to have 0V which is the sum of all potentials. Therefore, in this case, the floating metal shields can have the same effect as the grounded metal shield.

In conclusion, regardless of the portions of the antenna coils 340A, 340B, and 340C to which a high voltage is applied or the portions of the antenna coils 340A, 340B, and 340C to which a low voltage is applied, the metal shields 332A, 332B, and 332C located under the antenna coils 340A, 340B, and 340C are floated to have an equipotential and to have an average voltage, so that no capacitive coupling occurs.

According to the explained above, the metal shields 332A, 332B, and 332C are installed between the antenna coils 340A, 340B, and 340C and the inner space 302 (or the substrate 306) to be grounded or floated, so that Capacitive coupling occurring in a portion of the antenna coils 340A, 340B, and 340C to which a high voltage is applied and the resulting sheath can be prevented, thereby preventing damage to the dielectric window 350. Unlike the present embodiments, the metal shields 332A, 332B, and 332C may be installed under the dielectric window 350, and in this case, the insulating shields 334A, 334B, and 334C may be omitted.

In addition, the height of the receiving spaces 352A, 352B, 352C and the generating spaces 354A, 354B, 354C can be determined by considering the height of the antenna coils 340A, 340B, 340C, or the height of the metal shields 332A, 332B, and 332C, and the height of the insulating shields 334A, 334B, and 334C, plasma density, etc.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention may be applicable to a various apparatus for manufacturing semiconductor or a various method for manufacturing semiconductor.

What is claimed is:

1. An apparatus for processing substrate with a plasma, the apparatus comprising:
a chamber forming an inner space in which a processing gas is supplied;
a substrate holder installed in the inner space to support a substrate;
a dielectric window positioned on the substrate holder;
at least one antenna installed outside the dielectric window to generate an induced plasma from the processing gas supplied to the inner space; and
at least one metal shield installed between the antenna and the induced plasma.

2. The apparatus of claim 1, wherein the metal shield has a shape corresponding to the antenna, and the metal shield is floating.

3. The apparatus of claim 1, wherein the metal shield has a shape corresponding to the antenna, and the metal shield is grounded.

4. The apparatus of claim 1, wherein the dielectric window comprising:
a plurality of accommodating spaces recessed from an upper surface of the dielectric window, the metal shield and the antenna are accommodated sequentially from the inside of the accommodating space; and
a plurality of generating space recessed from a lower surface of the dielectric window to be located at the same height as the antenna, so that the induced plasma is generated between the accommodating spaces,
wherein the accommodating spaces and the generating spaces are alternately disposed from the center of the dielectric window toward the edge of the dielectric window.

5. The apparatus of claim 1, wherein the antenna comprising:
a first antenna having a ring-shape of a first diameter; and
a second antenna having a ring-shape of a second diameter, the second diameter is larger than the first diameter,
wherein the accommodating spaces comprising:
a ring-shaped first accommodating space in which the first antenna is accommodated; and
a ring-shaped second accommodating space in which the second antenna is accommodated.

6. The apparatus of claim 1, wherein the metal shield has a plurality of slits formed radially from the center of the antenna.

7. The apparatus of claim 1, the apparatus further comprising:
an insulating shield installed between the antenna and the metal shield.
